(19) United States
(12) Patent Application Publication
(10) Pub. No.: US 2003/0170583 A1
(43) Pub. Date: Sep. 11, 2003

(54) Heat treatment apparatus and a method for fabricating substrates

(75) Inventors: Sadao Nakashima, Tokyo (JP); Tomoharu Shimada, Tokyo (JP); Kenichi Ishiguro, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Nakano-ku (JP)

(21) Appl. No.: 10/373,754

(22) Filed: Feb. 27, 2003

(30) Foreign Application Priority Data
Mar. 1, 2002 (JP) 2002-055574

(51) Int. Cl. H01L 21/477; H01L 21/324; H01L 21/42; H01L 21/26; F27D 3/12; F27D 1/00; F27D 5/00

(52) U.S. Cl. 432/241; 438/795; 438/799; 432/247; 432/253

(57) ABSTRACT

A heat treatment apparatus for performing a heat treatment on one or more substrates includes a substrate support device holding the substrates, the substrate support device having a main body and a contact portion being in contact with a substrate. A surface of the main body is made of a material different from that of the contact portion, and at least a surface of the contact portion is made of either glassy carbon or graphite.

### FIELD Of THE INVENTION

The present invention relates to an apparatus and method for fabricating semiconductor wafers, glass substrates and the like; and more particularly, to an apparatus and method for performing heat treatment on semiconductor wafers, glass substrates and the like.

### Background OF THE INVENTION

In a case where a plurality of silicon wafers or quartz substrates are processed in a vertical heat treatment furnace, a substrate support device (or boat) made of silicon carbide (SiC) or quartz has been widely used.

Referring to FIG. 12, there is illustrated a conventional substrate support device 1, which includes a top plate 2 and bottom plate 3, three (or four) support rods 4 disposed therebetween. A plurality of support portions 5, each in a form of horizontal groove, are vertically arranged in the supporting rods 4 at predetermined intervals to maintain substrates 6 such as silicon wafers or quartz substrates therein.

However, there are drawbacks in using such substrate support device 1 in a heat treatment apparatus. Specifically, when the heat treatment is performed at about 1000° C. or above, scratches are formed on the substrates 6 near the area of contact with the support portions 5. Moreover, slip lines are generated in silicon wafers and as a result the silicon wafers are adversely deformed. Furthermore, formations of such scratches or slip lines deteriorate the flatness of the substrates 6, which in turn may lead to a mask misalignment (due to misalignment of focal point or deformation of the substrate) in a lithography process, which is one of the crucial processes in the fabrication of LSI or LCD circuits, thereby making it difficult to precisely fabricate LSI or LCD circuits having desired patterns.

The culprits of such scratches and slip lines are thought to be as follows:

When the substrate support device, holding a plurality of silicon wafers at approximately room temperature, is inserted into a reaction furnace heated to a range from about 600 to 700° C., there occurs a temperature difference between the periphery portion and the central portion in each silicon wafer held therein (see, e.g., Japanese Patent Application Laid-Open No. 1993-6894). As a result, the silicon wafer undergoes an elastic deformation, which leads to rubbing or colliding of the silicon wafer against the support portions 5 of the substrate support device made of SiC, which has a greater degree of hardness than the silicon wafer, or quartz or silicon having a substantially equivalent degree of hardness to the silicon wafer. The presence of such scratches on single crystalline silicon considerably lowers the yield point at which dislocation generation takes place. Accordingly, dislocation occurs in the scratched regions, while being processed at high temperature or the temperature is being raised, and further, slip lines grow and as a result, the substrates are deflected to assume a curved shape. Moreover, additional scratches are incurred while the temperature is being raised and such scratches lead to the generation of dislocations and slips during the heat treatment process, which is another attributing factor in causing a deflection. FIG. 13 illustrates exemplary scratches 7 and slip lines 8 formed on the silicon wafer 6, in which reference numeral 9 refers to a notch.

Similarly when the substrate support device, holding a plurality of quartz substrates, is inserted into a reaction chamber heated to a range from about 600° C. to 700° C., there occurs a temperature difference between the periphery portion and the central portion of each quartz substrate held therein. Therefore, the quartz substrate undergoes elastic deformation and such deformation leads to rubbing or colliding of the quartz substrate against the support portions 5 of the substrate support device made of SiC, which has a greater hardness than the quartz substrate, or of quartz or silicon, which has a virtually equivalent degree of hardness to the quartz substrate. FIG. 14 illustrates exemplary scratches 7 formed on quartz wafers.

### SUMMARY OF THE INVENTION

It is, therefore, an object of the present invention to provide an apparatus and method which is capable of performing a heat treatment on silicon wafers or quartz substrates while minimizing formation of scratches on the silicon wafers or the quartz substrates and suppressing formation of slip lines and deformation of silicon wafers to thereby provide high quality silicon wafers or quartz substrates.

To accomplish the aforementioned objects, the inventors of the present invention observed scratches incurred by conventional heat treatment apparatuses, and found that the scratches were only present on silicon wafers or quartz substrates and that scratches were rarely formed by a substrate support device made of SiC. Based on such observations about the scratches, the inventors assumed that the determining factor of the scratches made on the silicon wafers or quartz substrates was the greater hardness of the substrate support device than that of the silicon wafers or quartz substrates. Therefore, it was contemplated that such scratches would not be formed on the silicon wafer or quartz substrate, by disposing between the substrate support device and the silicon wafer or quartz substrate a substance which has a lower hardness than the silicon wafer or quartz substrate and further does not act as a contaminant during a silicon LSI fabricating process or quartz LCD fabricating process. In view of the above, a series of experiments and evaluations were carried out.

Exemplary materials having small hardness are glassy carbon, graphite or a combination thereof, e.g., a glassy carbon coated body, e.g., graphite, having a smaller hardness than glassy carbon. It was found that no scratch was generated both on the silicon wafer and on the quartz substrate during the heat treatment performed by a vertical heat treatment apparatus with such materials placed between the silicon wafer or quartz substrate and the substrate support device. Further, by performing a heat treatment (at 1200° C., for an hour and in an argon ambience) on silicon wafers while using the material with small hardness mentioned above, it was confirmed that such material produced no heavy metal (iron or copper) contaminants. Such confirmation was conducted by using a total reflection fluorescence X-ray analyzer.

In accordance with one aspect of the invention, there is provided a heat treatment apparatus for performing a heat treatment on one or more substrates, including: a substrate support device holding said one or more substrates, the substrate support device including a main body and a contact portion being in contact with a substrate, wherein a surface of the main body is made of a material different from that of the contact portion, and at least a surface of the contact portion is made of either glassy carbon or graphite.

In case silicon wafers or quartz substrates are used as the substrates, hardness of materials used in forming the substrates, main body and contact portion are as follows as listed in Table 1.

TABLE 1

| material | Vicker's hardness (kgf/mm²) |
|---|---|
| SiC | about 2500 |
| Silicon | 1000˜1050 |
| Quartz | 950˜1000 |
| Glassy Carbon | 400˜500 |
| Graphite | 200˜250 |
| Glassy Carbon coated Graphite | about 250 |

(wherein the hardness is Vickers hardness, hardness testers and hardness test method comply with JIS B7725 and JIS Z2244, respectively)

As described above, since the contact portion is made of a material having a smaller degree of hardness than the substrate in accordance with the present invention, the stress due to the collision between the substrate and the contact portion is reduced and thereby the generation of the scratch is prevented. Further, since the main body is made of SiC, silicon or quartz, it can retain proper strength at high temperature.

Additionally, when the glassy carbon coated graphite is used as the contact portion, the generation of impurities from the graphite is prevented. And such contact portion is less expensive and has a hardness close to that of graphite, which is also smaller than the one made of glassy carbon only.

Furthermore, when compared with such a substrate support device, which is wholly coated with a material having a smaller hardness than the substrate as disclosed in Japanese Patent Application Laid-Open No. 1994-5530, or the one, which is entirely made of glassy carbon as disclosed in Japanese Patent Application Laid-Open No. 1998-209064, the substrate support device of the present invention can be manufactured at a low cost since only the contact portion of the substrate support device is coated with a material having a smaller hardness than a substrate.

In accordance with another aspect of the invention, there is provided a semiconductor device fabricating method, including the steps of: loading one or more substrates into a reaction furnace; holding said one or more substrates by using a substrate support device wherein the substrate support device includes a main body and a contact portion being in contact with a substrate, and a surface of the main body is made of a material different from that of the contact portion, at least a surface region of the contact portion being made of glassy carbon or graphite; performing a heat treatment on said one or more substrates held in the substrate support device in the reaction furnace; and unloading said one or more substrates from the reaction furnace.

In accordance with still another aspect of the invention, there is provided with a substrate fabricating method, including the steps of: loading one or more substrates into a reaction furnace; holding said one or more substrates by using a substrate support device wherein the substrate support device includes a main body and a contact portion being in contact with a substrate, and a surface of the main body is made of a material different from that of the contact portion, at least a surface region of the contact portion being made of glassy carbon or graphite; performing a heat treatment on said one or more substrates held in the substrate support device in the reaction furnace; and unloading said one or more substrates from the reaction furnace.

### BRIEF DESCRIPTION OF THE DRAWINGS

The above and other objects and features of the present invention will become apparent from the following description of preferred embodiments given in conjunction with the accompanying drawings, in which:

FIG. 1 offers a perspective view of a heat treatment apparatus in accordance with a preferred embodiment of the present invention;

FIG. 2 sets forth a cross sectional view of a reaction furnace of the heat treatment process of FIG. 1;

FIG. 3 releases a vertical cross sectional view of a first preferred embodiment of a substrate support device used in the heat treatment apparatus of FIG. 1;

FIG. 4 exhibits a horizontal cross sectional view taken along line A-A in FIG. 3;

FIG. 5 illustrates a magnified vertical cross sectional view of the substrate support device of FIG. 3;

FIG. 6 describes a vertical cross sectional view of a second preferred embodiment of a substrate support device used in the heat treatment apparatus of FIG. 1;

FIG. 7 explains a horizontal cross sectional view taken along line B-B in FIG. 6;

FIG. 8 shows a magnified vertical cross sectional view of the substrate support device of FIG. 6;

FIG. 9 provides a vertical cross sectional view of a third preferred embodiment of a substrate support device used in the heat treatment apparatus of FIG. 1;

FIG. 10 displays a horizontal cross sectional view taken along line C-C in FIG. 9;

FIG. 11 is a magnified vertical cross sectional view of the substrate support device of FIG. 9;

FIG. 12 illustrates a perspective view of a conventional substrate support device;

FIG. 13 presents a bottom view of a silicon wafer processed by a conventional heat treatment apparatus; and

FIG. 14 depicts a bottom view of a quartz substrate processed by a conventional heat treatment apparatus.

### DETAILED DESCRIPTION OF THE PREFERRED EMBODIMENTS

The preferred embodiment of the present invention will now be described with reference to the accompanying drawings.

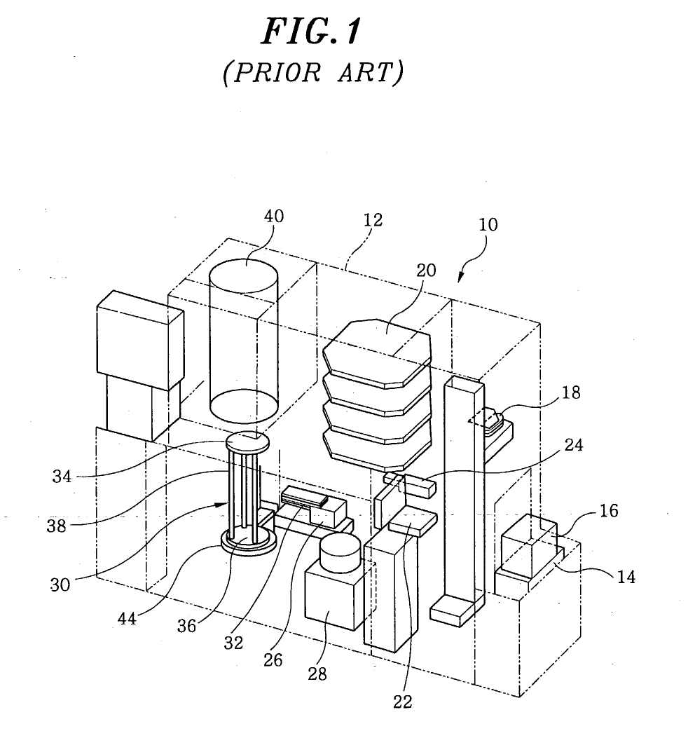

Referring to FIG. 1, there is illustrated a heat treatment apparatus 10 in accordance with a preferred embodiment of the present invention. The heat treatment apparatus 10, e.g., being a vertical type, includes a housing 12 for accommodating its main components therein. Connected to the housing 12 is a pod stage 14 onto which a pod 16 is transferred, wherein the pod 16 contains a plural number, e.g., 25, of substrates therein while keeping its cap (not shown) closed.

Installed in the housing 12 is a pod transfer device 18 which is correspondingly placed with the pod stage 14. And pod shelves 20, a pod opener 22 and a detector 24 for counting the number of the substrates in the pod 16 are disposed around the pod transfer device 18, wherein the pod transfer device 18 transfers the pod 16 therebetween. The detector 24 counts the number of the substrates in the pod 16 after the cap of the pod 16 is opened by the pod opener 22.

Further, in the housing 12, there are disposed a substrate transfer device 26, a notch aligner 28 and a substrate support device (or boat) 30. The substrate transfer device 26 is provided with an arm 32 which can extract a multiple number, e.g., 5, of substrates, and by employing such arm 32, the substrates can be transferred between the pod 16 placed on the pod opener 22, the notch aligner 28 and the substrate holder 30. The notch aligner 28 aligns the substrates by detecting notches or orientation flats formed therein. The substrate support device 30 has a top plate 34 and a bottom plate 36 which are connected by, for example, three, support rods 38 placed therebetween, wherein the support rods 38 can support a multiple number, e.g., 75, of substrates. It should be noted that the number of the support rods 38 can vary as long as they serve to support the substrates. The substrate support device 30 is loaded into a reaction furnace 40 as will be described later in detail.

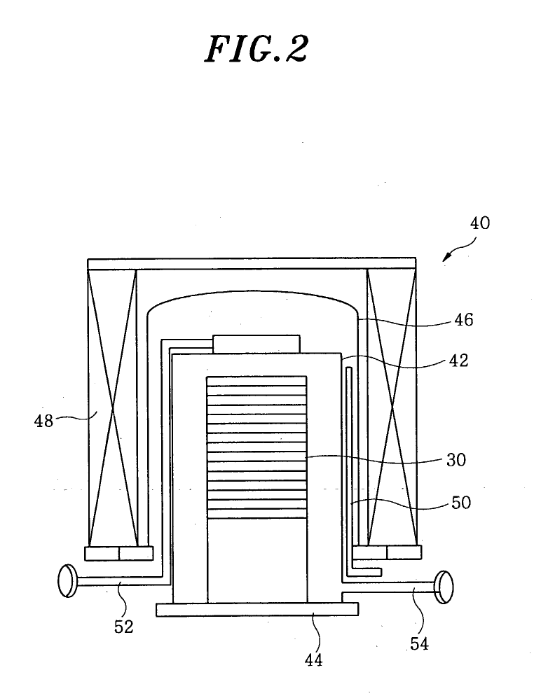

Referring to FIG. 2, there is illustrated a reaction furnace 40 including a reaction tube 42 into which the substrate support device 30 is loaded through an opening in the bottom end thereof. The opening is sealed by a cover 44. And the reaction tube 42 is surrounded by a heat diffusion tube 46 around which a heater 48 resides. Between the reaction tube 42 and the heat diffusion tube 46, there is installed a thermocouple 50 for measuring an inner temperature of the reaction furnace 40. In addition, a supply line for introducing a processing gas to the reaction tube 42, and an exhausting line for discharging same therefrom are connected thereto.

The operation of the heat treatment apparatus 10 will now be described.

Once the pod 16 containing the substrates is set on the pod stage 14, the pod 16 is transferred from the pod stage 14 to the pod shelf 20 by the pod transfer device 18 and stocked therein. Then, the pod transfer device 18 transfers the pod 16 stored in the pod shelf 20 to the pod opener 22. Next, the pod opener 22 opens the cap of the pod 16 thereon and the detector 24 counts the number of the substrates contained in the pod 16.

In the ensuing step, the substrate transfer device 26 extracts the substrates from the pod 16 on the pod opener 22 and moves them to the notch aligner 28. Then, the notch aligner 28 detects the notches of the substrates and rotates the wafers to align them by using the detected results. Afterwards the substrate transfer device 26 transfers the substrates from the notch aligner 28 to the substrate support device 30.

Such processes described above can be repeated, so that the substrate support device 30 is fully stocked with the substrates for one batch process. Then, the substrate support device 30 supporting the substrates for one batch is loaded into the reaction furnace 40 having the inner temperature at about 700° C. and the cover 44 closes the opening in the bottom end of the reaction tube 42. Next, the processing gas including, e.g., nitrogen, argon, hydrogen, and/or oxygen is introduced into the reaction tube 42 through the supply line 52. At this time, the substrates held in the substrate support device 30 are heated to have a temperature equal to or greater than, for example, about 1000° C. And the substrates held in the substrate support device 30 undergo a heat treatment process performed according to a predetermined temperature profile while the inner temperature of the reaction tube 42 is monitored by the thermocouple 50.

After the heat treatment is completed, the inner temperature of the reaction furnace 40 is reduced to about 700° C. and the substrate support device 30 is unloaded from the reaction tube 42 to a preset position where all the substrates held in the substrate support device 30 are then cooled down to a predetermined temperature. Afterwards, the substrate transfer device 26 extracts the processed substrates from the substrate support device 30 and the substrates are discharged into the pod 16 set on the pod opener 22. Next, the pod transfer device 18 transfers the pod 16 containing the processed substrates from the pod opener 22 to the pod shelf 20. Thereafter, the pod 16 is moved to the pod stage 14 by the pod transfer device 18.

The substrate support device 30 will now be described.

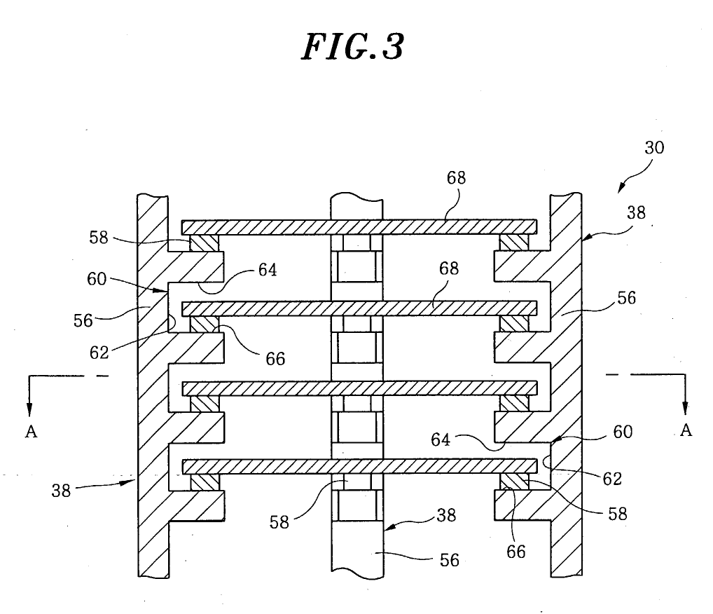

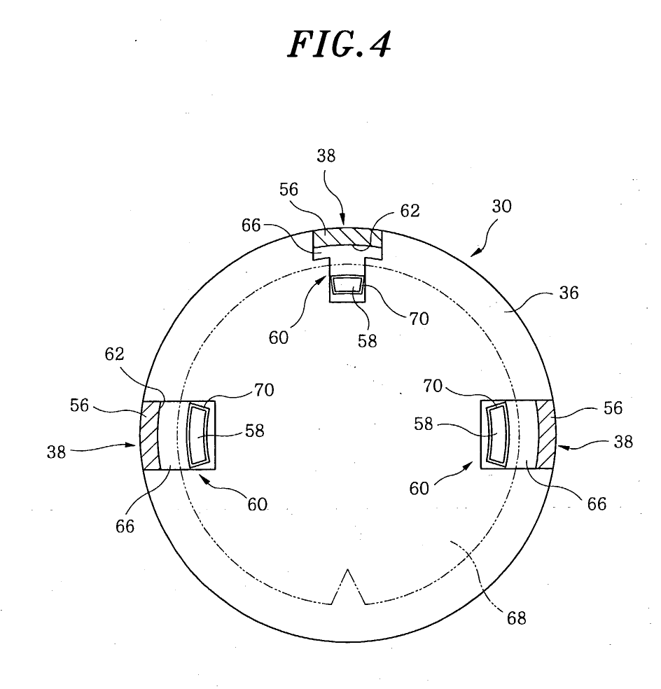

Referring to FIGS. 3 to 5, there is illustrated a substrate support device 30 in accordance with a first preferred embodiment of the present invention. The substrate support device 30 is provided with the three support bars 38 as aforementioned. Each support bar 38 has a main body 56 and a multiplicity of contact portions 58, wherein each contact portion 58 in contact with the substrate 68 supports the substrate 68 from the bottom. Each main body 56 is made of silicon carbide, silicon or quartz. And a multiplicity of support portions 60, facing an inner side of the substrate support device 30, are successively formed along the length direction of each support bar 38 with predetermined intervals therebetween. Each support portion 60 is in a form of a groove into which a periphery portion of the substrate 68 is inserted, and has an inner wall 62, an upper wall 64 and lower wall 66.

It should be noted that the vertical cross section of the support portion 60 can have a part of a circular, oval or any polygonal shape other than a rectangular shape shown in FIG. 3.

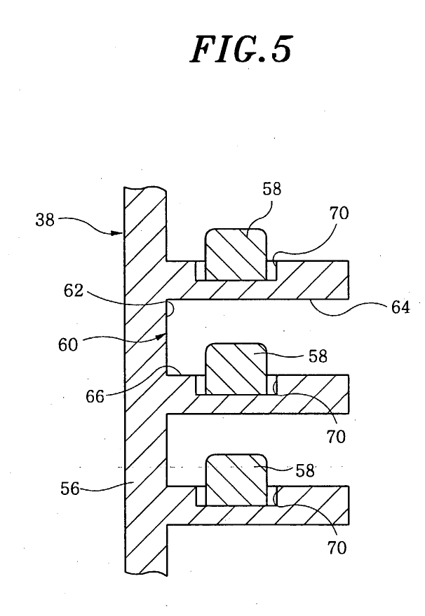

Additionally, as shown in FIG. 5, in the lower wall 66 of each support portion 60, there is formed a loading portion 70 into which the corresponding contact portion 58 is inserted. The width of the loading portion 70 is set to be greater than that of the contact portion 58 as will be described later, so that there exists a sideways clearance between the loading portion 70 and the contact portion 58. Since the contact portion 58 is inserted in the loading portion 70 without employing any adhesive material therebetween, and since there exists the sideways clearance, the contact portion 58 can be easily replaced with another.

The contact portion 58 is made of a different material from the main body 56 itself and its surface region, and has a smaller hardness than the substrate. The material of the contact portion 58 is, for example, glassy carbon, graphite or glassy carbon coated substance having a smaller hardness than glassy carbon, wherein the substance includes graphite. Such contact portion 58 is insertably configured to the loading portion 70, and corners of its upper end portion are rounded, so that it is prevented from scratching the substrate 68 when the substrate 68 is supported thereby.

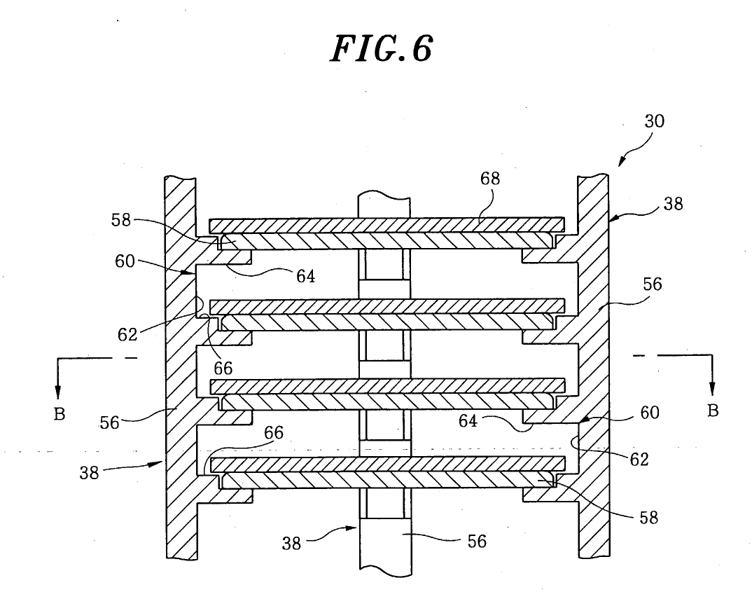

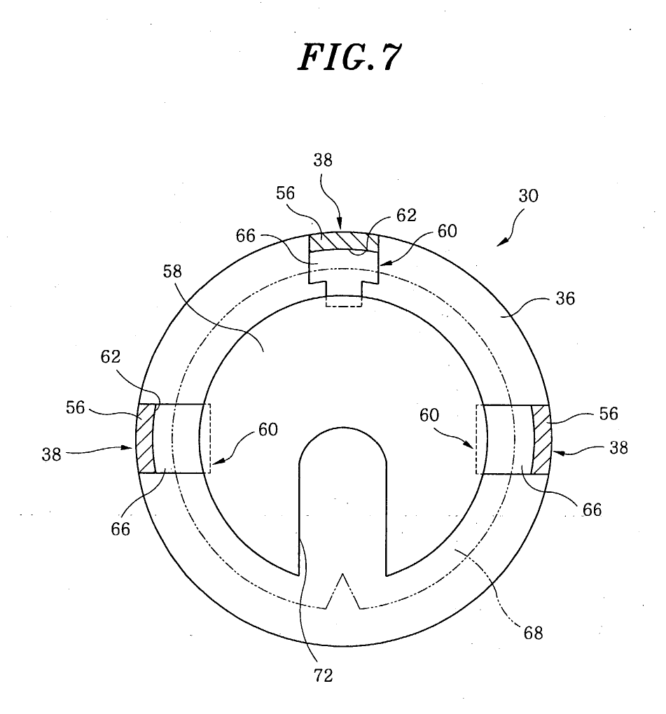

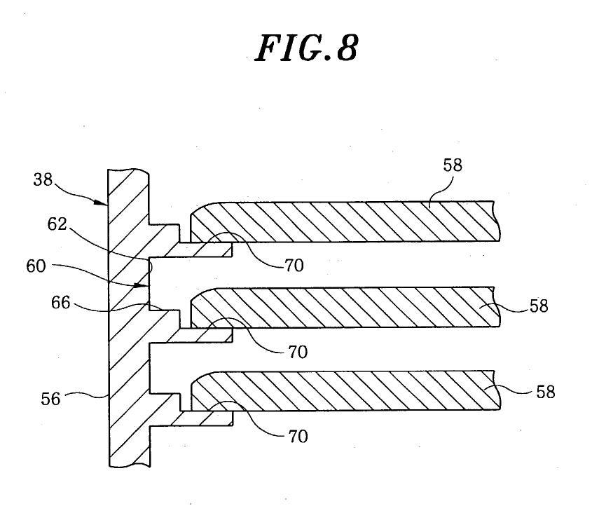

Referring to FIGS. 6 to 8, there is illustrated a substrate support device 30 in accordance with a second preferred embodiment of the present invention. In this preferred embodiment, each contact portion 58 is horseshoe-shaped and concurrently supported by all the three support bars 38. As shown in FIG. 8, formed on the end portion of each lower wall 66 of the support portion 60 is a loading portion 70 by which the periphery portion of the substrate is supported on its bottom. As described in the first preferred embodiment, corner regions of the upper portion of each contact portion 58 is also rounded.

Further, since the contact portion is removably installed at the main body, it can be installed only by placing itself on the loading portion, so that it can be easily replaced with new one when it is worn out, damaged or deteriorated.

Further, a cutaway portion 72 of the contact portion 58 provides a path through which tweezers, installed at one end portion of an arm of the substrate transfer device 26, are inserted for the transfer of the substrate.

Like reference numerals in the first and the second embodiment represent like parts and therefore the detailed descriptions thereof are omitted for the sake of simplicity.

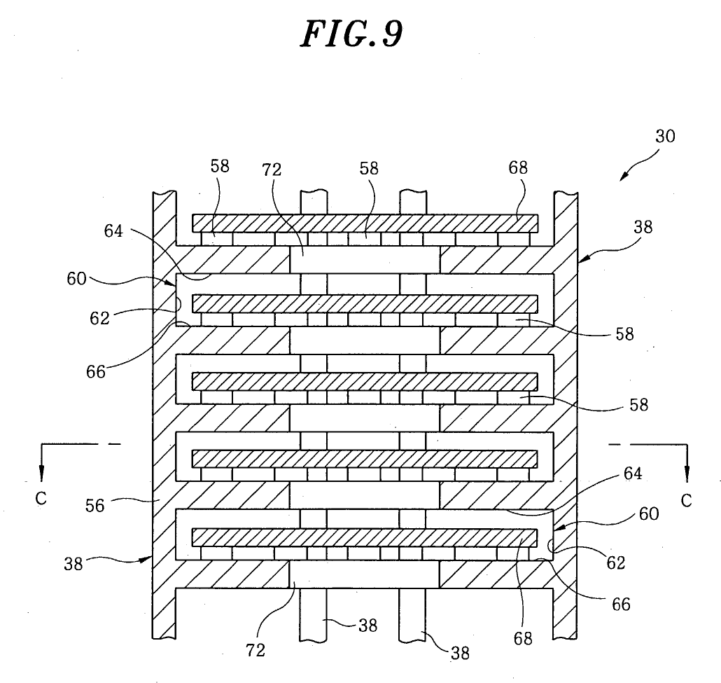

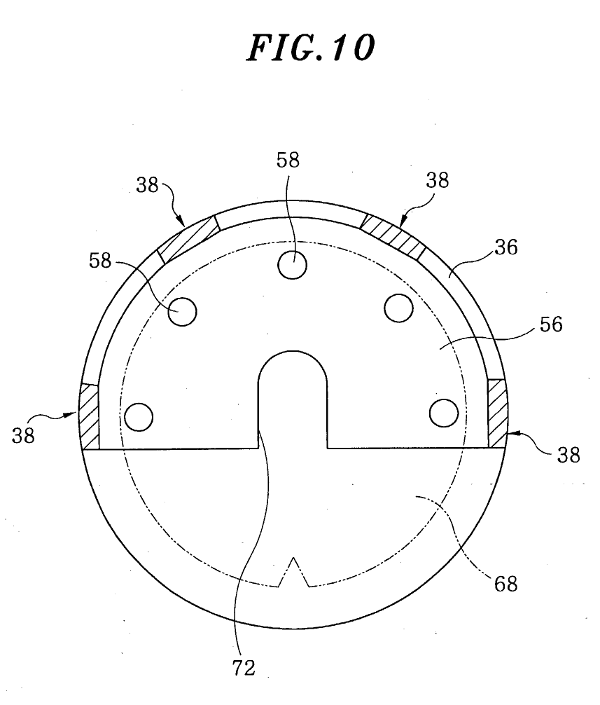

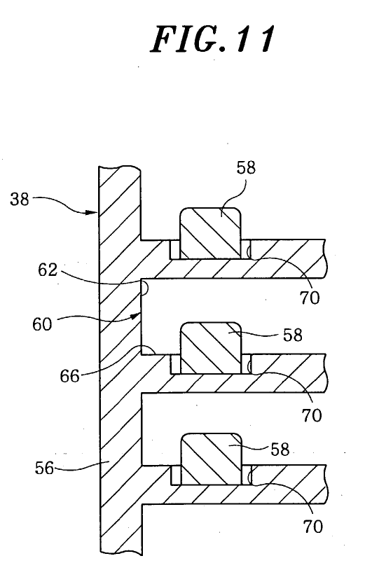

Referring to FIGS. 9 to 11, there is illustrated a substrate support device 30 in accordance with a third preferred embodiment of the present invention. In this preferred embodiment, the substrate support device 30 includes four support bars 38 connected by support portions 60 disposed along the length direction of the support bars 38 with predetermined intervals therebetween. Each support portion 60 has a horseshoe-shaped lower wall 66 on which five loading portions 70, in a form of a circular groove, are formed with predetermined intervals therebetween. As shown in FIG. 11, in each loading portion 70, a cylindrical contact portion 58 is disposed. And the corner regions of the upper portion of each contact portion 58 is also rounded as in the first and second preferred embodiments.

Further, since the contact portion is removably installed at the main body, it can be installed only by placing itself on the loading portion, so that it can be easily replaced with new one when it is worn out, damaged or deteriorated.

Further, the horseshoe-shaped lower wall 66 is provided with a cutaway portion 72 serving as a passageway to the tweezers installed at the end portion of an arm of the wafer transfer device 26.

Like reference numerals in first to third embodiments represent like parts. Therefore, detailed description thereof is omitted for the sake of simplicity.

The Examples and Comparative Examples will now be described.

### EXAMPLE

In Examples 1 to 3 set out below, the substrate support device of the first preferred embodiment was utilized, wherein the main body and the contact portions were made of silicon carbide and glassy carbon, respectively.

### Example 1

The substrate support device, supporting 75 sheets of 300 mm silicon wafers for one batch process, was inserted at a speed of 100 mm/min into a reaction furnace in an argon atmosphere. When the substrate support device was inserted thereinto, the reaction furnace temperature was set to be 700° C. The temperature was raised from 700° C. to 1200° C. More specifically, the temperature ramping rate was 16° C./min, from 700° C. to 1200° C. and 1.5° C./min from 1000° C. to 1200° C. And the temperature was maintained at 1200° C. for an hour. Then, the temperature was reduced from 1200° C. to 700° C. More specifically, temperature was reduced from 1200° C. to 1000° C. at a rate of 1.5° C./min, and from 1000° C. to 700° C. at a rate of 15° C./min. The reason for having lower rates in the range between 1000 and 1200° C. in both cases than those in the range between 700 and 1000° C. is to prevent slips, which are easily generated by the temperature nonuniformity caused by the sudden temperature change at high temperatures. The substrate support device was unloaded from the reaction furnace at a speed of 100 mm/min when the reaction furnace temperature reached 700° C.

In the ensuing step, the processed silicon wafers were observed by means of an optical differential microscope, and neither scratch nor slip line was found. Further, deflection of the silicon wafers was measured by means of a deflectometer, and the measurement results were equal to or less than 10 μm, which was substantially equal to a value measured before the process.

The warpage measurement was conducted for 10 sheets of the processed silicon wafers according to a method known by those skilled in the art. That is, after the silicon wafer was made stand vertically with respect to an optical axis of laser beam, the laser bean was emitted. Then, light reflected by the silicon wafer was measured to calculate the degree of deflection of the silicon wafer.

### Example 2

In this Example, experiment identical to that of Example 1 except that the holding temperature of the reaction furnace was 1080° C., was conducted. That is, the temperature of the reaction furnace raised from 700° C. to 1000° C. at a rate of 16° C./min, and from 1000° C. to 1080° C. at a rate of 1.5° C. Such rise in temperature was performed in a mixture gas ambience of 99.5% of argon gas and 0.5% of oxygen. Then, the temperature was held constant at 1080° C. for an hour in a 100% argon gas atmosphere. Afterwards, the temperature was reduced from 1080° C. to 1000° C. at a rate of 1.5° C./min, and from 1000° C. to 700° C. at a rate of 15° C./min in the 100% argon gas atmosphere. Other conditions were identical to those of the Example 1.

The experimental results showed no signs of generation of scratch, slip line, and increase in deflection of the wafers.

### Example 3

In this Example, an experiment identical to the experiment of Examples 1 and 2 except that the holding temperature of the reaction furnace was 1000° C., was conducted. That is, the temperature of the reaction furnace was raised from 700° C. to 1000° C. at a rate of 16° C./min in a mixture gas ambience of 99.5% of argon gas and 0.5% of oxygen. Then, the temperature was held at 1000° C. for two hours in a 100% argon gas ambience. Afterwards, the temperature was reduced from 1000° C. to 700° C. at a rate of 15° C./min in the 100% argon gas ambience. Other conditions were identical to those of the Example 1.

The experimental results showed no signs of generation of a scratch, slip line, and increase in deflection.

In each of Examples 4 to 6 set below, the wafer support device in accordance with the first preferred embodiment was used, wherein the main components of the main body and contact portion were made of SiC and glassy carbon coated graphite, respectively.

### Example 4

Same heat treatment as in Example 1 was performed. The experimental results showed no signs of generation of a scratch, slip line, and increase in deflection.

### Example 5

A heat treatment identical to that of Example 2 with an exception of the ambience gas of 100% Ar was performed. The experimental results showed no signs of generation of a scratch, slip line, and increase in deflection.

### Example 6

An identical heat treatment as in Example 3 with an exception of the ambience gas of 100% Ar was performed. The experimental results showed no signs of generation of a scratch, slip line, and increase in deflection.

In each of Examples 7 to 9 set below, the wafer support device in accordance with the second preferred embodiment was used, wherein the main body and the contact portion were made of SiC and graphite, respectively.

### Example 7

Same heat treatment as in Example 1 was performed. The experimental results showed no signs of generation of a scratch, slip line, and increase in deflection.

### Example 8

Same heat treatment as in Example 5 was performed. The experimental results showed no signs of generation of a scratch, slip line, and increase in deflection.

### Example 9

Same heat treatment as in Example 6 was performed. The experimental results showed no signs of generation of a scratch, slip line, and increase in deflection.

### Example 10

Same experiments as in Examples 1 to 9 were performed by using the substrate support device in accordance with the second preferred embodiment of the present invention, wherein the main component of the main body was replaced with silicon. The experimental results showed no signs of generation of a scratch, slip line nor, and increase in deflection.

### Example 11

Same experiments as in Examples 2, 3, 5, 6, 8 and 9 were carried out by using the aforementioned substrate support device in accordance with the third preferred embodiment of the present invention, wherein the main body was made of quartz. The experimental results showed no signs of generation of a scratch, slip line, and increase in deflection.

### Example 12

Same experiments as in Examples 2, 3, 5, 6, 8 and 9 were carried out by using quartz substrates and the aforementioned substrate support device in accordance with the first preferred embodiment, wherein the main body was made of SiC and the contact portion was made of glassy carbon, glassy carbon coated graphite or graphite. And the diameter and thickness of the quartz wafer were 300 mm and 1.0 mm, respectively. The experimental results showed no signs of generation of a scratch, slip line, and increase in deflection when examined by the optical differential microscope.

### Example 13

Same experiment as in Example 12 was performed after the main body was replace with one made of silicon. The experimental results showed no signs of generation of a scratch, slip line, and increase in deflection.

### Example 14

Same experiment as in Example 12 was performed after the main body was replace with one made of quartz. The experimental results showed no signs of generation of a scratch, slip line, and increase in deflection.

### Comparative Example 1

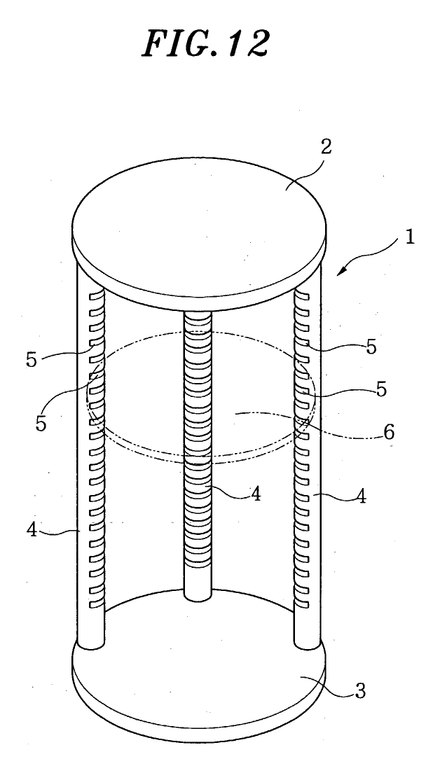

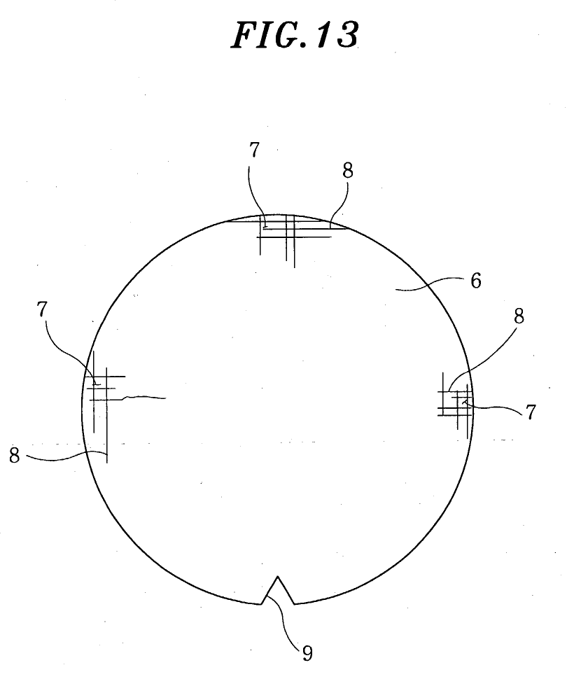

Same experiment as in Example 1 was performed by using the conventional one shown in FIG. 12, wherein the silicon wafers were supported directly by the conventional substrate support device made of SiC. In three portions on the bottom surface of each silicon wafer respectively corresponding to three support portions of the substrate support device, scratches having a size of 50-300 μm, a depth of 5 μm and a height of 10 μm were observed. And a plurality of slip lines having a length of 4-30 mm were made due to the scratches (shown in FIG. 13). In addition, the deflection of the silicon wafers, which was 10 μm before the heat treatment, was 60-90 μm thereafter. The number, N, of the silicon wafers used in this Comparative Example was 10.

### Comparative Example 2

Same experiment as in Example 2 was performed by using the conventional one shown in FIG. 12, wherein the silicon wafers were supported directly by the substrate support device composed of silicon. In three portions on the bottom surface of each silicon wafer respectively corresponding to three support portions of the substrate support device, scratches having a size of 20-100 μm were incurred. And a plurality of slip lines having a length of 2-30 mm were made due to the scratches. In addition, the deflection of the silicon wafers, which was about 10 μm before the heat treatment, was 60-80 μm after the heat treatment. The number, N, of the silicon wafers used in this Comparative Example was 10.

### Comparative Example 3

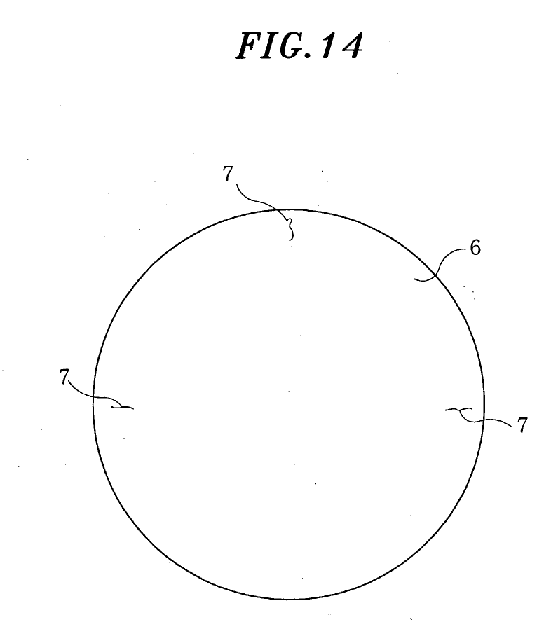

Same experiment as in Example 3 was performed by using the conventional one shown in FIG. 12, wherein the quartz substrates were supported directly by the substrate support device composed of quartz. The diameter and thickness of each quartz substrate were 300 mm and 1.0 mm, respectively. In three portions on the bottom surface of each quartz substrate respectively corresponding to three support portions of the substrate support device, scratches having a size of 100-200 μm were incurred (as shown in FIG. 14). And maximum height of the scratches was about 20 μm.

Further, 300 mm in diameter silicon wafers or quartz substrates can be replaced with silicon wafers or quartz substrates having a diameter of 200 mm or 400 mm, or even in a rectangular shape. Additionally, although the Comparative Examples make no mention of a combination of a substrate support device made of silicon and a quartz substrate, or a combination of a substrate support device made of quartz and a silicon wafer, in such case it is likely that scratches are made on substrates since the hardness of silicon is substantially equal to that of quartz.

As described above, the apparatus in accordance with the preferred embodiments of the present invention can perform a heat treatment on silicon wafers or quartz substrates while minimizing formation of scratches and suppressing formation of slip lines, and thereby can provide high quality silicon wafers or substrates.

The heat treatment apparatus of the preferred embodiment of the present invention can be applicable to various heat treatment processes performed on substrates.

One application of the inventive heat treatment apparatus to a process incorporated in a procedure for fabricating SIMOX (separation by implanted oxygen) wafers, one type of SOI (Silicon On Insulator) wafer, will now be illustrated.

First, oxygen ions are implanted into single crystalline silicon wafers by means of an ion implanter.

Then, an annealing process is performed on the wafers implanted with oxygen ions by the heat treatment apparatus of the present invention, for example, at a higher temperature of 1300˜1400° C., e.g., at 1350° C. or above, and in Ar, O₂ ambience, so that SIMOX wafers, each having SiO₂ layer therein, are manufactured.

Further, the heat treatment apparatus of the present invention can be applicable to a process incorporated in a procedure for fabricating hydrogen annealed wafers. In such case, an annealing process is performed on the wafers at about 1200° C. in a hydrogen ambience by the heat treatment apparatus of the present invention. As a result, the crystallinity of the wafer can be enhanced and defects in the surface layer of the wafer on which IC is to be formed can be decreased.

Additionally, the heat treatment apparatus of the present invention can also be applied to a process incorporated in a procedure for fabricating epitaxial wafers.

In the aforementioned high temperature annealing processes performed as the first process of the substrate fabrication procedure, the generation of slip lines can be prevented by using the heat treatment apparatus of the present invention.

The heat treatment apparatus of the present invention is also applicable to a heat treatment process in the course of fabricating semiconductor devices.

More specifically, it is preferable to apply the heat treatment apparatus of the present invention to a heat treatment process performed at relatively a high temperature, for example, a thermal oxidation process such as wet oxidation, dry oxidation, pyrogenic oxidation and HCI oxidation, and thermal diffusion process for diffusing dopants such as boron (B), phosphorous (P), arsenic (As), antimony (Sb) and so forth in a semiconductor thin layer.

In such a heat treatment process performed as a part of the semiconductor device fabricating procedure, the generation of slip lines can be prevented by using the heat treatment apparatus of the present invention.

While the invention has been shown and described with respect to the preferred embodiments, it will be understood by those skilled in the art that various changes and modifications may be made without departing from the spirit and scope of the invention as defined in the following claims.

What is claimed is:

1. A heat treatment apparatus for performing a heat treatment on one or more substrates, comprising:
a substrate support device holding said one or more substrates, the substrate support device including a main body and a contact portion being in contact with a substrate,
wherein a surface of the main body is made of a material different from that of the contact portion, and at least a surface of the contact portion is made of either glassy carbon or graphite.

2. The heat treatment apparatus of claim 1, wherein the contact portion is formed of a first material and a second material, the first material is being coated with the second material and the first material having a hardness smaller than that of the second material.

3. The heat treatment apparatus of claim 2, wherein the second material is glassy carbon.

4. The heat treatment apparatus of claim 3, wherein the first material is graphite.

5. The heat treatment apparatus of claim 1, wherein the main body is made of carbon silicide, silicon or quartz.

6. The heat treatment apparatus of claim 1, wherein the contact portion is removably disposed on the main body.

7. The heat treatment apparatus of claim 1, wherein the substrate support device holds the substrates in a substantially horizontal manner such that they are vertically stacked with a predetermined interval therebetween.

8. The heat treatment apparatus of claim 1, wherein the heat treatment is performed by heating said one or more substrates at about 1000° C. or above.

9. The heat treatment apparatus of claim 1, wherein the heat treatment is performed by heating said one or more substrates at about 1350° C. or above.

10. A semiconductor device fabricating method, comprising the steps of:
loading one or more substrates into a reaction furnace;
holding said one or more substrates by using a substrate support device wherein the substrate support device includes a main body and a contact portion being in contact with a substrate, and a surface of the main body is made of a material different from that of the contact portion, at least a surface region of the contact portion being made of glassy carbon or graphite;
performing a heat treatment on said one or more substrates held in the substrate support device in the reaction furnace; and
unloading said one or more substrates from the reaction furnace.

11. A substrate fabricating method, comprising the steps of:
loading one or more substrates into a reaction furnace;
holding said one or more substrates by using a substrate support device wherein the substrate support device includes a main body and a contact portion being in contact with a substrate, and a surface of the main body is made of a material different from that of the contact portion, at least a surface region of the contact portion being made of glassy carbon or graphite;
performing a heat treatment on said one or more substrates held in the substrate support device in the reaction furnace; and
unloading said one or more substrates from the reaction furnace.
